(19) United States
(12) Patent Application Publication
(10) Pub. No.: US 2025/0359354 A1
(43) Pub. Date: Nov. 20, 2025

(54) METHOD OF FABRICATION OF A PHOTOVOLTAIC ARRAY

(71) Applicant: Garmin International, Inc., Olathe, KS (US)

(72) Inventors: MohammadAli AkhavanKazemi, Rousset (FR); Cyril A. Chappaz, Rousset (FR)

(21) Appl. No.: 19/209,331

(22) Filed: May 15, 2025

Related U.S. Application Data
(60) Provisional application No. 63/649,002, filed on May 17, 2024.

(51) Int. Cl. H10F 19/90

(52) U.S. Cl. CPC H10F 19/904

(57) ABSTRACT

A method for fabricating a photovoltaic element array includes forming a cell electrode on a portion of an upper surface of a substrate; forming a conductive contact on a perimeter of the upper surface of the substrate; depositing a photoresist layer onto the cell electrode; depositing a low surface energy layer onto the photoresist layer, the low surface energy layer including hydrophobic materials; removing a first portion of the photoresist layer and the low surface energy layer to create a plurality of columns of photoresist material and low surface energy material distributed in an array pattern; and depositing a photovoltaic material onto the first portion of the cell electrode in between the columns of photoresist material and low surface energy material.

### RELATED APPLICATIONS

The current patent application is a non-provisional utility patent application which claims priority benefit, with regard to all common subject matter, under 35 U.S.C. § 119 (e) of earlier-filed U.S. Provisional Application Ser. No. 63/649,002; entitled “PHOTOVOLTAIC MICRO-PATTERNING”; and filed May 17, 2024. The Provisional application is hereby incorporated by reference, in its entirety, into the current patent application.

### BACKGROUND

Electronic devices worn on a user's wrist include smart watches and fitness bands and typically have a color display which displays data and images. In addition, the devices are powered by a rechargeable battery. To increase the amount of time before the battery needs to be charged, the electronic device may also include a solar cell of photovoltaic elements which is positioned over the display.

### BRIEF DESCRIPTION OF DRAWINGS

Embodiments of the present technology are described in detail below with reference to the attached drawing figures, wherein:

FIG. 1 is a top plan view of a photovoltaic cell assembly, constructed in accordance with various embodiments of the current technology;

FIGS. 2A, 2B, 2C, 2D, 2E, 2F, 2G, 2H, 2I, and 2J include schematic cross-sectional views of the photovoltaic cell assembly during various steps of a method of fabricating the photovoltaic cell assembly;

FIG. 3 includes a listing of at least a portion of the steps of a method of fabricating the photovoltaic cell assembly; and

FIG. 4 includes a listing of at least a portion of the steps of another method of fabricating the photovoltaic cell assembly.

The drawing figures do not limit the present technology to the specific embodiments disclosed and described herein. The drawings are not necessarily to scale, emphasis instead being placed upon clearly illustrating the principles of the technology.

### DETAILED DESCRIPTION OF THE TECHNOLOGY

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the present technology. The following detailed description is, therefore, not to be taken in a limiting sense. The scope of the present technology is defined only by the appended claims, along with the full scope of equivalents to which such claims are entitled.

Relational and/or directional terms, such as “above”, “below”, “up”, “upper”, “upward”, “down”, “lower”, “downward”, “top”, “bottom”, “outer”, “inner”, “left”, “right”, etc., along with orientation terms, such as “horizontal” and “vertical”, may be used throughout this description. These terms retain their commonly accepted definitions and are used with reference to embodiments of the technology and the positions, directions, and orientations thereof shown in the accompanying figures. However, embodiments of the technology in practice may be positioned and oriented in other ways or move in other directions. Therefore, the terms do not limit the scope of the current technology.

The term “generally electrically conductive material(s)” is used throughout this description and refers to metals and/or metal alloys which are capable of conducting electric current.

Embodiments of the present technology relate to an improved method for fabricating an array of photovoltaic (PV) elements which may be integrated into a display module of a wrist-worn electronic device in order to provide an electric charge to a battery of the electronic device. The array includes a plurality of spaced apart PV elements with transparent windows positioned therebetween—making the array semi-transparent. When the array is placed on top of display components, such as an organic light-emitting diode (OLED) or active matrix OLED (AMOLED) display, the display is visible underneath the array. An example of the electronic device with the PV element array integrated into the display module is described in U.S. Pat. No. 11,841,686, entitled “Integrated energy-collecting display module with core out”, and filed Nov. 9, 2020, which is incorporated by reference, in its entirety, into the current patent application, except where inconsistent with the teachings of the current patent application.

Traditional methods for fabricating an array of spaced-apart active elements with windows positioned therebetween may involve creating a continuous layer of active element material and then using harsh chemicals or solvents with radiation and etching steps to remove a portion of the active element material to create the windows. These methods are generally incompatible with processing PV/solar cell material, especially sensitive organic or organometallic solar material such as dye sensitized solar cells, polymer solar cells, or perovskite solar cells. Fabrication methods of examples of the present technology address these problems by not using harsh chemicals or solvents to form a PV element array. An exemplary method includes forming a plurality of spaced-apart (but electrically interconnected to a peripheral continuous PV area) columns on an upper surface of a substrate. Each column may include a layer of photoresist material positioned underneath a layer of hydrophobic, low surface energy material. The PV material is mixed with a solvent to create a solution that is applied to the upper surface of the substrate. The solution settles on the substrate between the columns and avoids the hydrophobic, low surface energy material. As the solution dries, the solvent evaporates, leaving the PV material on the substrate, having a plurality of spaced-apart PV elements with PV windows (formed by the columns) positioned therebetween in an array formation.

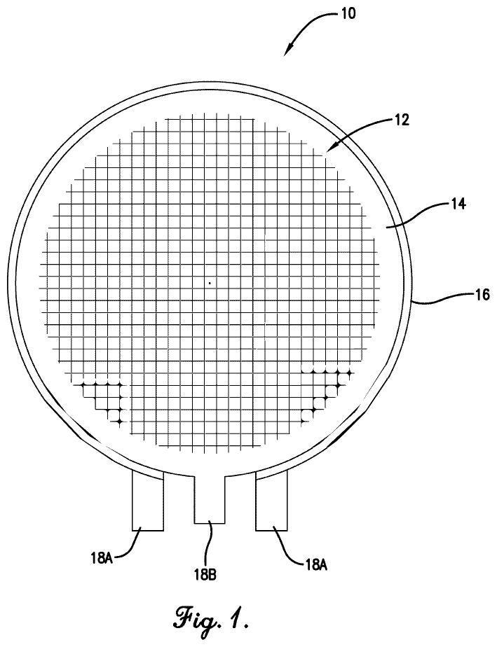

Embodiments of the technology will now be described in more detail with reference to the drawing figures. Referring initially to FIG. 1, a photovoltaic (PV) cell assembly 10 is shown. The PV cell assembly 10 broadly comprises a PV element array 12, a PV ring 14, a conductive contact 16, and a plurality of connectors 18. The exemplary PV cell assembly 10 is depicted in the figures as having a generally round or circular perimeter. However, the PV cell assembly 10 may have a perimeter with nearly any geometric shape, such as oval, triangular, quadrilateral, pentagonal, hexagonal, and so forth. Typically, the PV cell assembly 10 has a perimeter shape that corresponds to a perimeter shape of the display module of the electronic device in which the PV cell assembly 10 is to be integrated.

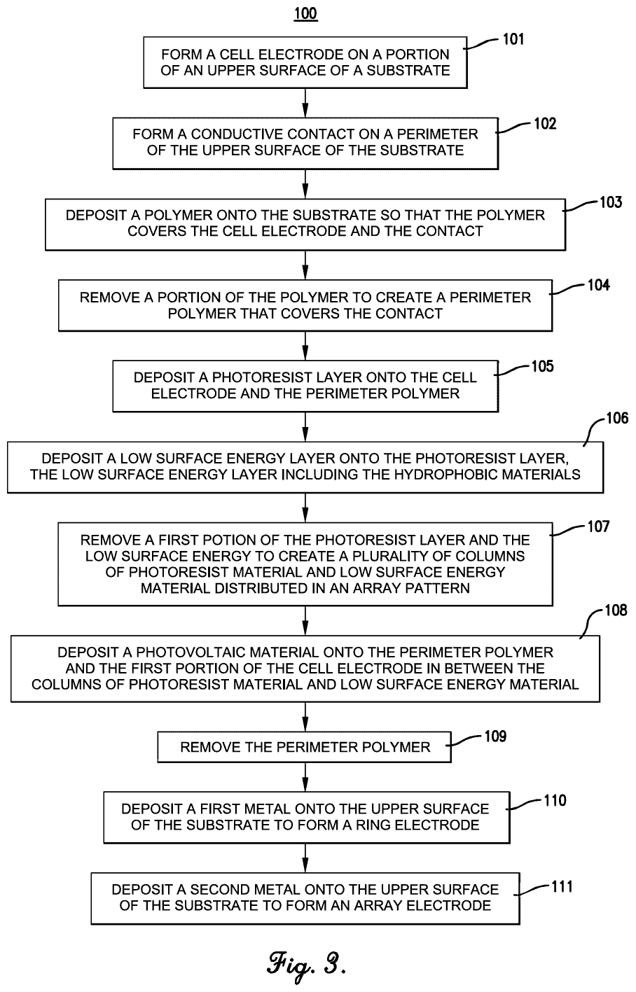

The PV element array 12 is positioned within a central area of the PV cell assembly 10. The PV element array 12 generally converts photonic energy to electrical energy and, as shown in FIG. 3D, includes a plurality of PV elements 20 and a plurality of PV windows 22. In one example, the PV elements 20 are electrically interconnected to the PV ring 14, and laterally spaced apart from one another and distributed in a two-dimensional array pattern, wherein a respective one of the PV windows 22 is positioned between adjacent PV elements 20. In some embodiments, the pattern may be triangular or hexagonal, such that each PV element 20 is positioned or oriented at a 60-degree angle with respect to adjacent PV elements 20. In other embodiments, the pattern may be an orthogonal grid or the like, such that each PV element 20 is positioned or oriented at a 90-degree angle with respect to adjacent PV elements 20. In still other embodiments, the pattern may be that each PV element 20 is positioned or oriented with respect to adjacent PV elements 20 at an angle other than 60 degrees or 90 degrees. However, any shape or configuration may be employed.

Each PV element 20 is formed from a plurality of layers of components positioned one on top of another to create a stack, as shown in FIG. 3D. Starting with the lowest layer to the highest layer, the PV element 20 stack includes a glass substrate 24, a cell electrode 26, a PV material 28, and an array electrode 30. The glass substrate 24 is formed from silicon-based material(s), sapphire-based material(s), or combinations thereof and is generally transparent to light in the visible spectrum. The cell electrode 26 includes a grid or other configuration that is formed from generally electrically conductive material(s) as well as material(s) that surround the grid and are generally transparent to light in the visible spectrum, so that the cell electrode 26 is at least partially transparent. In some embodiments, the cell electrode 26 can be formed of a layer of conductive oxides, metals, or the like as opposed to presenting a grid configuration. The cell electrode 26 improves or enhances electrical charge collection from the PV material 28 across the PV element array 12 toward the connectors 18A via the conductive contact 16. The PV material 28 is formed from one or more sublayers of semi-conductive materials to form a structure such as a positive-intrinsic-negative (p-i-n) junction. The PV material 28 has the advantages of low cost as well as low toxicity compared to some other photovoltaic material(s), but it is understood that other photovoltaic material(s) may be employed without departing from the present teachings such as silicon, micro-crystalline silicon, perovskite, or combinations thereof, e.g., stacked in sublayers. For example, the PV material 28 may alternatively be formed from microcrystalline silicon, polycrystalline silicon, monocrystalline silicon, perovskite-based compounds, organic photovoltaic materials, or combinations thereof. These materials may be deposited as single layers or as multilayered stacks with various doping profiles, junction types, or tandem configurations to enhance spectral absorption and power conversion efficiency. The array electrode 30 is formed from generally electrically conductive material(s) that are not necessarily transparent.

Each PV window 22 is formed from the glass substrate 24 and the cell electrode 26 as well as a respective one of a plurality of columns 32 of a photoresist material positioned underneath a low surface energy material. The photoresist material may include polymers that react when exposed to radiation such as ultraviolet (UV) light. The low surface energy material includes hydrophobic material(s) such as siloxane, polydimethylsiloxane (PDMS), fluorinated silanes, fluoropolymer coatings, and the like, or combinations thereof. The surface energy of the low surface energy material may be less than or equal to approximately 30 milli Newtons per meter (mN/m), with a contact angle between water and one or more surfaces of the low surface energy material being greater than or equal to approximately 90 degrees. The height, or thickness, of each column 32 has a value of greater than or equal to approximately 1 micrometer (μm) in some embodiments. In other embodiments, the value may be greater than or equal to approximately 1.5 μm.

In some embodiments, the use of permanent photoresist structures, such as the columns 32 described above, may be omitted. Instead, a removable polymer may be applied to the periphery—covering the conductive contact 16 and surrounding regions—as well as over the connectors 18A. This removable polymer serves as a temporary mask during deposition steps (e.g., of PV material 28 or metals) and is subsequently removed to expose the underlying structures.

Additionally, in some embodiments, the inclusion of the low surface energy material on top of the photoresist columns 32 is optional. While the low surface energy material—such as siloxane, polydimethylsiloxane (PDMS), fluorinated silanes, fluoropolymer coatings, or combinations thereof—is effective in preventing solvent-based PV material solutions from settling on the columns, alternative configurations may also achieve this result. For example, any size or shape of column 32 may be employed, and in some embodiments where the height of the column 32 approaches or exceeds approximately 4 micrometers (μm), domed, curved, or other contoured column shapes may be utilized. These alternative shapes can provide sufficient barrier characteristics to redirect or repel the PV solution during deposition, thereby achieving the desired patterning effect without requiring a hydrophobic, low surface energy coating. In some embodiments, the contoured shape of the column is formed by controlling the reflow characteristics of the photoresist material during a thermal baking step, which causes the material to dome or taper due to surface tension effects.

The PV ring 14 has a ring or annular shape, encircles the PV element 20, and has a similar structure to the PV elements 20 of the PV element array 12. That is, the PV ring 14 includes the glass substrate 24, the cell electrode 26, the PV material 28, and a ring electrode 34. The ring electrode 34 is similar to the array electrode 30 and is formed from generally electrically conductive material(s), but can be formed during a different step of a method for fabricating the PV element array 12. In addition, the ring electrode 34 is electrically connected to at least a portion of the array electrode 30.

The conductive contact 16 has a ring or annular shape, encircles the PV ring 14 with an optional gap therebetween, and is formed from generally electrically conductive material(s). The conductive contact 16 collects all of the electric charge(s) generated by the PV element array 12 and the PV ring 14 through the cell electrode 26.

The connectors 18 are each formed from generally electrically conductive material(s) and include first and second connectors 18A that electrically connect to the conductive contact 16 and a third connector 18B that electrically connects to the ring electrode 34 and the array electrode 30. The connectors 18 also electrically connect to one or more flexible printed circuits (FPCs), not shown in the figures.

The PV cell assembly 10 is typically utilized in an orientation that is inverted from what is shown in the figures. For example, when the PV cell assembly 10 is integrated into the display module of the electronic device, the PV cell assembly 10 is oriented such that the glass substrate 24 is facing, or exposed to, ambient light, such as sunlight, and the ring electrode 34 and the array electrode 30 are positioned underneath the glass substrate 24.

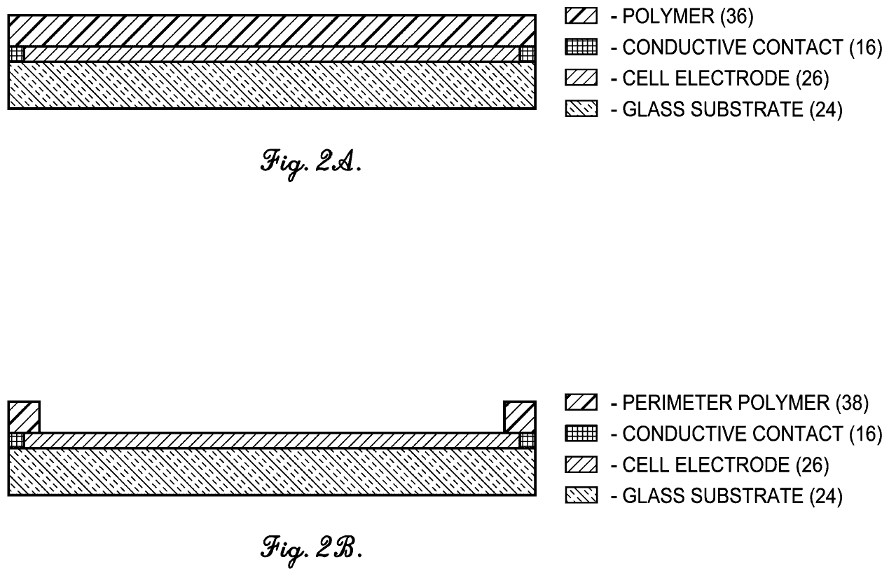

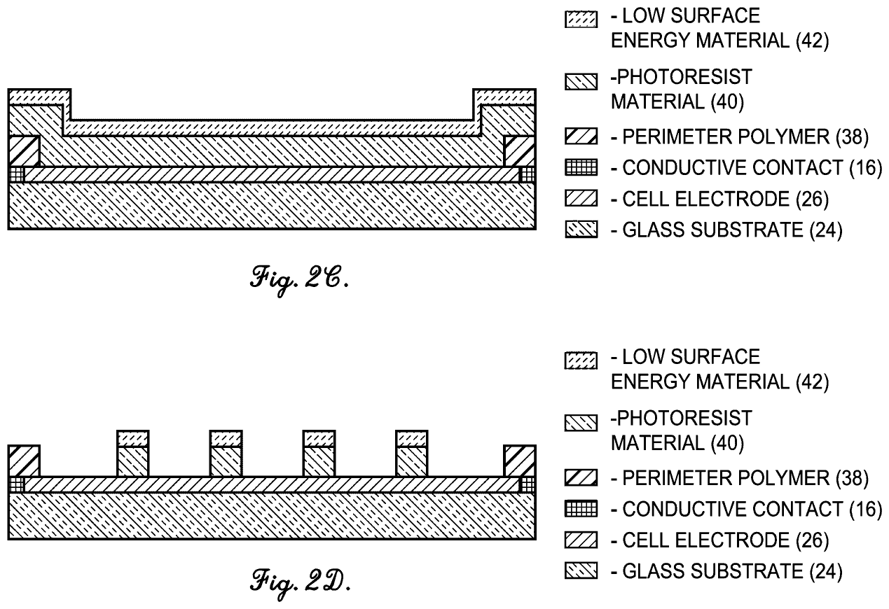

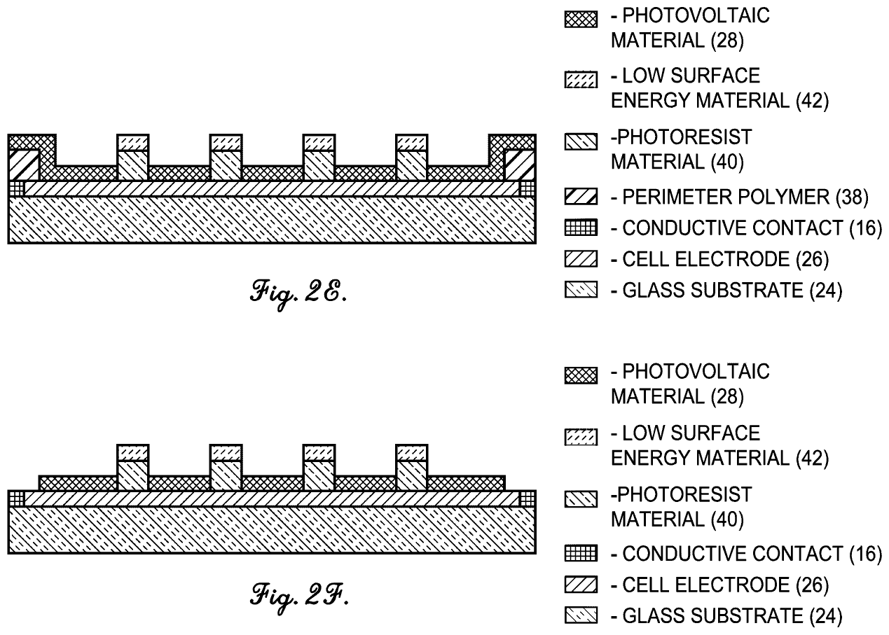

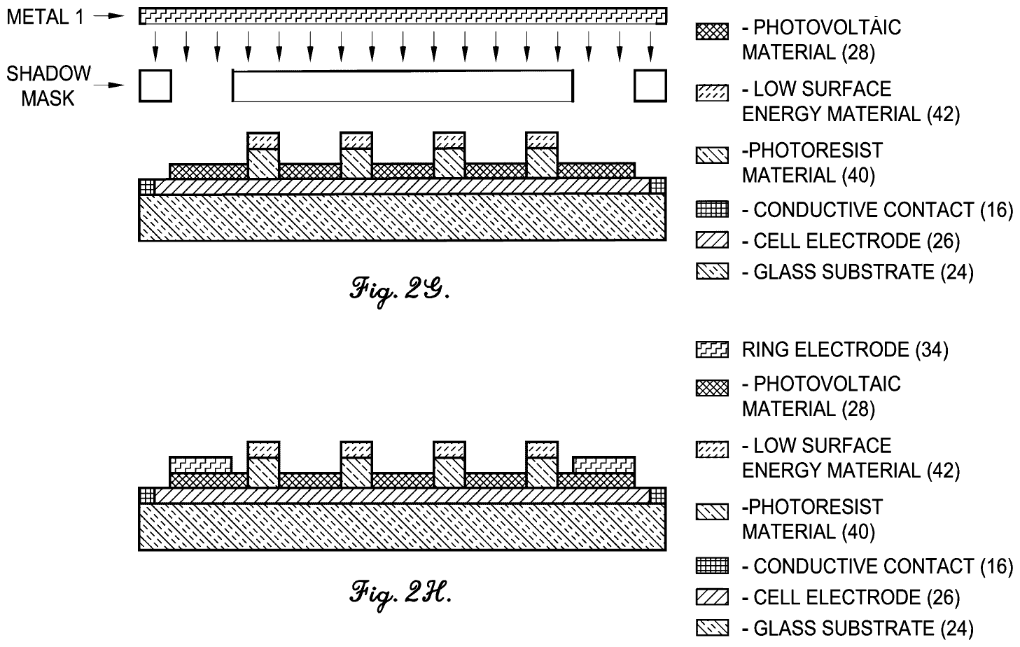

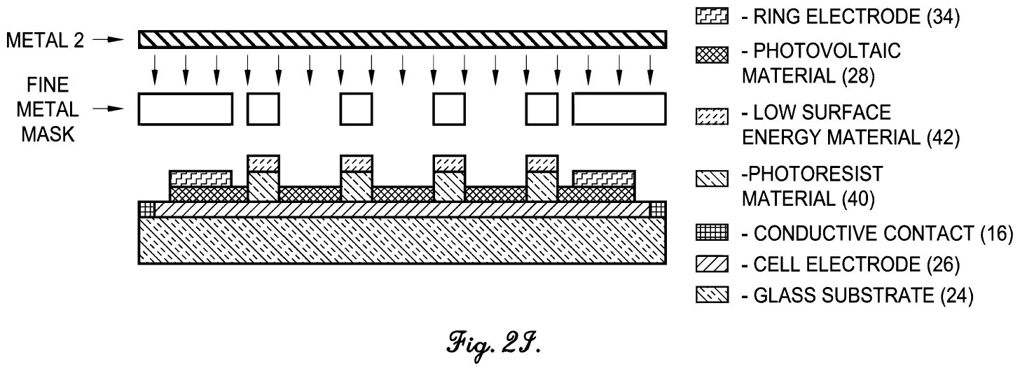

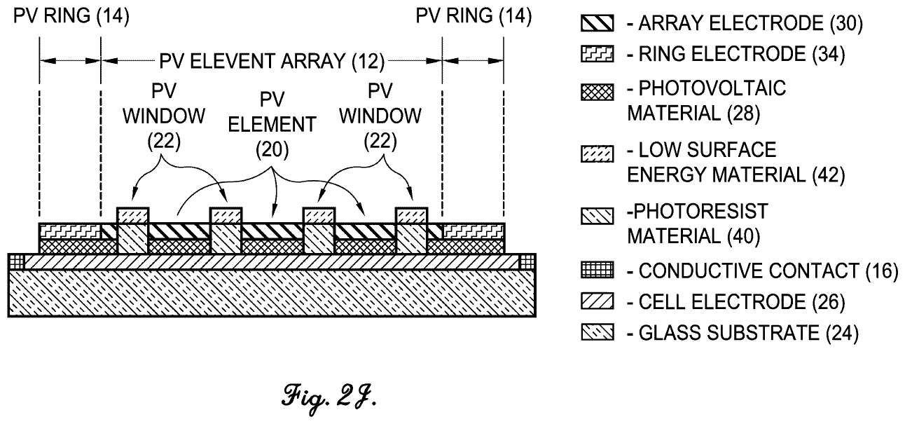

Referring to FIGS. 2A-2J, cross sectional views of the PV cell assembly 10 are shown at various developmental stages during the implementation of an exemplary method 100 for fabricating the PV cell assembly 10. Referring to FIG. 3, at least a portion of the steps of the method 100 is shown. Variations to the steps may be performed. The steps may be performed in the order shown in FIG. 3, or they may be performed in a different order. Furthermore, some steps may be performed concurrently as opposed to sequentially. In addition, some steps may be optional or may not be performed. The components of FIGS. 2A-2J are optional in some configurations and are illustrated as only examples of embodiments of the present invention.

Referring to step 101 and FIG. 2A, a cell electrode 26 is formed on a portion of an upper surface of a substrate 24. The substrate 24 is formed from silicon-based material(s), sapphire-based material(s), or combinations thereof and is generally transparent to light in the visible spectrum. The cell electrode 26 is formed from generally electrically conductive material(s) as well as material(s) that are generally transparent to light in the visible spectrum, so that the cell electrode 26 is at least partially transparent as described above. The cell electrode 26 has an area that is smaller than an area of the substrate 24 and is positioned on an inner region of the substrate 24. The cell electrode 26 may be formed using deposition or printing techniques.

Referring to step 102 and FIG. 2A, a conductive contact 16 is formed on a perimeter of the upper surface of the substrate 24. The conductive contact 16 has a ring or annular shape, encircles and is in contact with the cell electrode 26, and is formed from generally electrically conductive material(s). The conductive contact 16 may be formed using deposition or printing techniques.

Referring to step 103 and FIG. 2A, a polymer 36 is deposited onto the substrate 24 so that the polymer 36 covers portions of the cell electrode 26, conductive contact 16, and/or connectors 18A. In some configurations, polymer 36 may be deposited only on connectors 18A. The polymer 36 may be formed from polymers such as chlorinated poly(para-xylylene), commonly referred to as “parylene C,” and may be deposited using chemical vapor deposition (CVD) or other appropriate deposition techniques. Alternatively, the polymer 36 can be directly printed on the desired area, for example using screen-printing. The polymer 36 functions primarily as a perimeter masking or passivation layer, ensuring that subsequently deposited PV material 28 does not inadvertently coat the conductive contact 16 or flow into the gap surrounding the cell electrode 26.

However, in some embodiments, this step may be optional for the peripheral area. Specifically, the need for the polymer 36 may be obviated when the configuration of the columns 32 or the properties of the PV material solution inherently prevent undesired deposition or flow of PV material onto the perimeter region. For example, when the columns 32 are formed with sufficient height—such as approaching or exceeding approximately 4 micrometers—or include dome-shaped, tapered, or otherwise contoured geometries, they may create physical and capillary barriers that inhibit lateral spread of the PV solution beyond the intended active area. Additionally, when no low surface energy material is employed on the columns, and alternative deposition techniques such as fine metal masking or evaporative processes may be used, the polymer 36 may no longer be necessary to achieve pattern fidelity. Referring to step 104 and FIG. 2B, a portion of the polymer 36 is removed to create a perimeter polymer 38 that covers the contact 16. The polymer 36 portion may be removed using patterning, etching, mechanical methods, or the like. In embodiments where step 103 is optional, step 104 need not be performed. Additionally, in some configurations, polymer 36 may be applied only to connectors 18A so that perimeter polymer 38 is not created.

Referring to step 105 and FIG. 2C, a layer of photoresist material 40 is deposited onto the cell electrode 26 and the perimeter polymer 38. The photoresist material 40 includes polymers that react when exposed to radiation such as UV light. The photoresist material 40 may be applied using spin coating, spray coating, slit coating, additive printing like screen printing, combinations thereof, and the like

Referring to step 106 and FIG. 2C, a layer of low surface energy material 42 is deposited onto the photoresist material 40. The low surface energy material 42 is formed from hydrophobic material(s) such as siloxane, polydimethylsiloxane (PDMS), fluorinated silanes, fluoropolymer coatings, and the like, or combinations thereof. The surface energy of the low surface energy material may be less than or equal to approximately 30 milli Newtons per meter (mN/m), with a contact angle between water and one or more surfaces of the low surface energy material being greater than or equal to approximately 90 degrees. The low surface energy material 42 may be applied using spin coating or by Plasma Enhanced Chemical Vapour Deposition (PECVD). The thickness, or height, of the combination of the photoresist material 40 and the low surface energy material 42 has a first value of greater than or equal to approximately 1 micrometer (μm) in some embodiments. In other embodiments, the first value may be greater than or equal to approximately 1.5 μm. As described at length above, step 106 is optional in some configurations, such as those where step 103 is optional due to the geometrical configuration of columns 32.

Referring to step 107 and FIG. 2D, a first portion of a combination of the photoresist material 40 and the low surface energy material 42 is removed to create a plurality of columns 32 of photoresist material and low surface energy material laterally spaced apart from one another and distributed in a two-dimensional array pattern. The first portion of the combination of the photoresist material 40 and the low surface energy material 42 is removed from the perimeter polymer 38 and a first portion of the cell electrode 26. The first portion of the combination of the photoresist material 40 and the low surface energy material 42 may be removed by etching such that the first portions of the photoresist material 40 and the low surface energy material 42 are removed at roughly the same time. In some embodiments, the pattern of the array of columns 32 may be triangular or hexagonal, such that each column 32 is positioned or oriented at a 60-degree angle with respect to adjacent columns 32. In other embodiments, the pattern may be an orthogonal grid or the like, such that each column 32 is positioned or oriented at a 90-degree angle with respect to adjacent columns 32. In still other embodiments, the pattern may be that each column 32 is positioned or oriented with respect to adjacent columns 32 at an angle other than 60 degrees or 90 degrees.

Referring to step 108 and FIG. 2E, a photovoltaic (PV) material 28 is deposited onto the first portion of the cell electrode 26 in between the columns 32 of photoresist material and low surface energy material. The PV material 28 may be formed from doped amorphous silicon, silicon, micro-crystalline silicon, semi-conductive polymers or dyes, crystalline organo-metallic perovskite, or combinations thereof. The PV material 28 is deposited using solution processing in which a solute, such as inorganic nanoparticles, is dissolved in a solvent, such as water, chlorinated solvents, organic solvents, etc., to form a solution. The solution is applied to the upper surface of the substrate 24 and onto the conductive contact 16, the perimeter polymer 38, and the cell electrode 26 with the array of columns 32 positioned on its upper surface. The solution flows on the cell electrode 26 between the columns 32 and to the perimeter polymer 38. Given that the columns 32 are capped with hydrophobic, low surface energy material 42, the water-based solution does not flow onto (the top of) the columns 32. Furthermore, the columns 32 have a height above the surface of the cell electrode 26 that is great enough to discourage the solution to flow onto (the top of) the columns 32. The solution is allowed to dry in-situ, so that the water evaporates-leaving the PV material 28 deposited on the cell electrode 26 in between the columns 32.

Referring to step 109 and FIG. 2F, the perimeter polymer 38 is removed. The perimeter polymer 38 may be removed by etching, mechanical peeling, and/or through other methods. Any PV material 28 that resided on the perimeter polymer 38 is removed as well. In embodiments where the polymer 38 is not deposited to begin with, as described above at length, step 109 is optional.

Referring to step 110 and FIG. 2G, a first metal is deposited onto the upper surface of the substrate 24 which includes the conductive contact 16 and the PV material 28 positioned between the columns 32 of photoresist material and low surface energy material. The first metal is deposited through a shadow mask which includes one or more openings that are aligned with a perimeter of the PV material 28 on the cell electrode 26. Thus, as shown in FIG. 2H, after the deposition, a ring electrode 34 is formed, which also completes the PV ring 14.

Referring to step 111 and FIG. 2I, a second metal is deposited onto the upper surface of the substrate 24 which includes the conductive contact 16, the PV material 28 positioned between the columns 32 of photoresist material and low surface energy material, and the ring electrode 34. The second metal is deposited through a fine metal mask which includes a plurality of openings that are aligned with the PV material 28 positioned between the columns 32 of photoresist material and low surface energy material. (The columns 32 themselves and the ring electrode 34 are covered, or masked.) Thus, as shown in FIG. 2J, after the deposition, an array electrode 30 is formed, which also completes the PV element array 12—including a plurality of electrically-interconnected and spaced apart PV elements 20 and a plurality of PV windows 22 positioned therebetween.

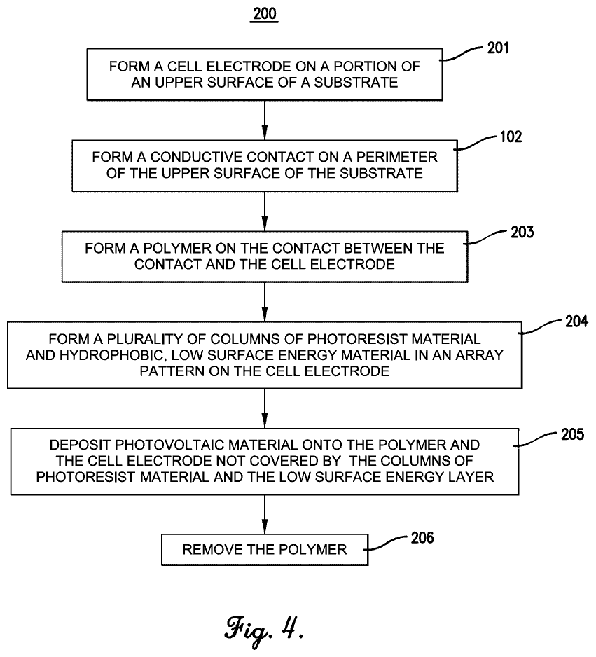

Referring to FIG. 4, at least a portion of the steps of another method 200 for fabricating a PV cell assembly 10 is shown. Variations to the steps may be performed. The steps may be performed in the order shown in FIG. 4, or they may be performed in a different order. Furthermore, some steps may be performed concurrently as opposed to sequentially. In addition, some steps may be optional or may not be performed.

Method 100 generally employs photolithographic techniques to form patterned column structures comprising a photoresist base with an optional low surface energy coating. These columns facilitate solution-based deposition of photovoltaic (PV) material in defined regions. In contrast, Method 200, described below, generally provides a simplified or alternative fabrication approach by using nanoimprint lithography to directly form columns from hydrophobic, UV—or thermoset-curable materials, or by eliminating columns altogether through direct patterning of PV material via fine metal masks.

Referring to step 201 and FIG. 2B, a cell electrode 26 is formed on a portion of an upper surface of a substrate 24. The substrate 24 is formed from silicon-based material(s), sapphire-based material(s), or combinations thereof and is generally transparent to light in the visible spectrum. The cell electrode 26 includes a grid or other configuration that is formed from generally electrically conductive material(s) as well as material(s) that surround the grid and are generally transparent to light in the visible spectrum, so that the cell electrode 26 is at least partially transparent. The cell electrode 26 has an area that is smaller than an area of the substrate 24 and is positioned on an inner region of the substrate 24. The cell electrode 26 may be formed using deposition or printing techniques.

Referring to step 202 and FIG. 2B, a conductive contact 16 is formed on a perimeter of the upper surface of the substrate 24. The conductive contact 16 has a ring or annular shape, encircles the cell electrode 26 with a gap therebetween, and is formed from generally electrically conductive material(s). The conductive contact 16 may be formed using deposition or printing techniques.

Referring to step 203 and FIG. 2B, a perimeter polymer 38 is formed on the conductive contact 16. In some embodiments, the perimeter polymer 38 may be formed by screen printing a resin or paste. In other embodiments, the perimeter polymer 38 may be formed by selective deposition of polymer material(s).

Referring to step 204 and FIG. 2D, a plurality of columns 32 of photoresist material and hydrophobic, low surface energy material are formed-distributed in an array pattern on the cell electrode 26. In some embodiments, each column 32 may include a lower portion, positioned on top of the cell electrode 26, formed from photoresist material, and an upper portion formed from hydrophobic, low surface energy material. In other embodiments, each column 32 may include a (hydrophobic) low surface energy UV-curable material. The columns 32 may be formed using nano-imprinting lithography in which the low surface energy UV-curable material is deposited on the upper surface of the cell electrode 26. A mold, having three-dimensional features which correspond to the array pattern of the columns 32, is pressed onto the low surface energy UV-curable material so that the material flows into the three-dimensional features. UV light may be applied to the low surface energy UV-curable material in order to cure and solidify the material. When the mold is removed, the array pattern of the columns 32 is formed. Alternatively, a thermoset low surface energy material may be used. When the mold is pressed on to the thermoset low surface energy material, heat may be applied in order to set the material. After removal of the mold, the array pattern of the columns 32 remains.

Referring to step 205 and FIG. 2E, a PV material 28 is deposited onto the polymer 36 and the cell electrode 26 not covered by the columns 32 of photoresist material and the low surface energy material. The PV material 28 may be formed from doped amorphous silicon, silicon, micro-crystalline silicon, semi-conductive polymers or dyes, crystalline organo-metallic perovskite, or combinations thereof. The PV material 28 is deposited using solution processing in which a solute, such as inorganic nanoparticles, is dissolved in a solvent, such as water, to form a solution. The solution is applied to the upper surface of the substrate 24 and onto the conductive contact 16, the perimeter polymer 38, and the cell electrode 26 with the array of columns 32 positioned on its upper surface. The solution flows on the cell electrode 26 between the columns 32 and to the perimeter polymer 38. Given that the columns 32 are capped with hydrophobic, low surface energy material 42, the solvent-based solution does not flow onto (the top of) the columns 32. Furthermore, the columns 32 have a height above the surface of the cell electrode 26 that is great enough to discourage the solution to flow onto (the top of) the columns 32. The solution is allowed to dry in-situ, so that the solvent evaporates—leaving the PV material 28 deposited on the cell electrode 26 in between the columns 32.

Alternatively, the PV material 28 may be deposited onto the cell electrode 26 only and without the need for the columns 32 of photoresist material and the low surface energy material. Instead, the PV material 28 is directly deposited onto the cell electrode 26 using a fine metal mask such as the one shown in FIG. 2I. The fine metal mask has openings that correspond to the area occupied by the PV elements 20 and not the area occupied by the columns 32. Thus, the PV material 28 may be evaporated through the fine metal mask onto the cell electrode 26 in the array pattern. In such embodiments, step 204 may be omitted by employing a direct patterning approach using the fine metal masks and 205 may be modified such that PV material is deposited directly onto the cell electrode through a precision-aligned shadow mask or fine metal stencil. As a result, steps 204 and 205 become conditional—if the direct masking approach is employed, step 204 (column formation) is not performed, and step 205 is executed with the metal mask guiding deposition rather than relying on surface energy barriers.

Referring to step 206 and FIG. 2F, the perimeter polymer 38 is removed. The perimeter polymer 38 may be removed by etching, mechanical peeling, and/or through other methods. Any PV material 28 that resided on the perimeter polymer 38 is removed as well.

After step 206, the ring electrode 34 and the array electrode 30 may be formed as shown in FIGS. 2G-2J and described above for steps 110 and 111.

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112 (f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

1. A method for fabricating a photovoltaic element array, the method comprising:
forming a cell electrode on a portion of an upper surface of a substrate;
forming a conductive contact on a perimeter of the upper surface of the substrate;
depositing a photoresist layer onto the cell electrode;
depositing a low surface energy layer onto the photoresist layer, the low surface energy layer including hydrophobic materials;
removing a first portion of the photoresist layer and the low surface energy layer to create a plurality of columns of photoresist material and low surface energy material distributed in an array pattern; and
depositing a photovoltaic material onto the first portion of the cell electrode in between the columns of photoresist material and low surface energy material.

2. The method of claim 1, wherein the cell electrode is at least partially transparent.

3. The method of claim 1, further including depositing a polymer onto the substrate using chemical vapor deposition.

4. The method of claim 3, wherein the polymer includes chlorinated poly(para-xylylene) polymer.

5. The method of claim 1, wherein the hydrophobic materials include siloxane.

6. The method of claim 1, wherein the hydrophobic materials include polydimethylsiloxane.

7. The method of claim 1, wherein the hydrophobic materials include fluorine.

8. A method for fabricating a photovoltaic element array, the method comprising:
forming a cell electrode on a portion of an upper surface of a substrate;
forming a conductive contact on a perimeter of the upper surface of the substrate, the contact circumscribing the cell electrode;
forming a polymer on the contact;
forming a plurality of columns of photoresist material and hydrophobic, low surface energy material distributed in an array pattern on the cell electrode;
depositing a photovoltaic material onto the polymer and the cell electrode not covered by the columns of photoresist material and hydrophobic, low surface energy material; and
removing the polymer.

9. The method of claim 8, further comprising removing the photovoltaic material deposited on the polymer.

10. The method of claim 8, wherein the cell electrode is at least partially transparent.

11. The method of claim 8, wherein the polymer is formed by screen printing a resin.

12. The method of claim 8, wherein the polymer is formed by selective deposition.

13. The method of claim 8, wherein the columns of photoresist material and hydrophobic, low surface energy material are formed by nano-imprinting lithography.

14. A method for fabricating a photovoltaic element array, the method comprising:
forming a cell electrode on a portion of an upper surface of a substrate;
forming a conductive contact on a perimeter of the upper surface of the substrate, the contact circumscribing the cell electrode;
depositing a polymer onto the substrate so that the polymer covers the cell electrode, the contact, and the gap;
removing a portion of the polymer to create a perimeter polymer that covers the contact;
depositing a photoresist layer onto the cell electrode and the perimeter polymer;
depositing a low surface energy layer onto the photoresist layer, the low surface energy layer including hydrophobic materials;
removing a first portion of the photoresist layer and the low surface energy layer to create a plurality of columns of photoresist material and low surface energy material distributed in an array pattern, wherein the first portion of the photoresist and the low surface energy layer is removed from the perimeter polymer and a first portion of the cell electrode;
depositing a photovoltaic material onto the perimeter polymer and the first portion of the cell electrode in between the columns of photoresist material and low surface energy material;
removing the perimeter polymer;
depositing a first metal onto the upper surface of the substrate to form a ring electrode; and
depositing a second metal onto the upper surface of the substrate to form an array electrode.

15. The method of claim 14, further comprising removing the photovoltaic material deposited on the perimeter polymer.

16. The method of claim 14, wherein the cell electrode is at least partially transparent.

17. The method of claim 14, wherein the polymer is deposited using chemical vapor deposition.

18. The method of claim 14, wherein the polymer includes chlorinated poly(para-xylylene) polymer.

19. The method of claim 14, wherein the hydrophobic materials is selected from the group consisting of siloxane, polydimethylsiloxane, and fluorine.

20. A method for fabricating a photovoltaic element array, the method comprising:
forming a cell electrode on a portion of an upper surface of a substrate;
forming a conductive contact on a perimeter of the upper surface of the substrate;
depositing a photoresist layer onto the cell electrode;
removing a first portion of the photoresist layer to create a plurality of columns of photoresist material distributed in an array pattern; and
depositing a photovoltaic material onto the first portion of the cell electrode in regions between the columns of photoresist material,
wherein each of the plurality of columns has a height greater than or equal to approximately 4 micrometers and comprises a contoured geometry effective to inhibit deposition of the photovoltaic material onto an upper surface of the column.
